(19) United States
(12) Patent Application Publication
(10) Pub. No.: US 2024/0133945 A1
(43) Pub. Date: Apr. 25, 2024

(54) MODULAR LOW LEVEL CONTACT RESISTANCE TESTING APPARATUS FOR PROCESSOR SOCKETS

(71) Applicants: Mohanraj Prabhugoud, Portland, OR (US); David Shia, Portland, OR (US); Lejie Liu, Portland, OR (US); Silver Alfonso Rodriguez Estrada, Zapopan (MX); Min Pei, Camas, WA (US); Ralph V. Miele, Hillsboro, OR (US); Caleb Million Tessema, Portland, OR (US)

(72) Inventors: Mohanraj Prabhugoud, Portland, OR (US); David Shia, Portland, OR (US); Lejie Liu, Portland, OR (US); Silver Alfonso Rodriguez Estrada, Zapopan (MX); Min Pei, Camas, WA (US); Ralph V. Miele, Hillsboro, OR (US); Caleb Million Tessema, Portland, OR (US)

(21) Appl. No.: 18/401,133

(22) Filed: Dec. 29, 2023

(51) Int. Cl. G01R 31/28

(52) U.S. Cl. CPC G01R 31/2863; G01R 31/2808; G01R 31/2886

(57) ABSTRACT

A low level contact resistance (LLCR) testing apparatus comprises a test board, an interface board, and a patch board. The test board comprises a processor socket. The interface board connects to both the test board and the patch board. The patch board connects to a contact resistance tester. An LLCR system comprising the LLCR testing apparatus and a contact resistance tester can be portable. The test board can accommodate thermal management solutions of varying sizes and types. Different test board designs can accommodate different socket-processor configurations and the different test boards can be easily accommodated by an LLCR testing apparatus due to its modular design.

### BACKGROUND

Low Level Contact Resistance (LLCR) metrology is an important capability for qualifying processor socket designs and analyzing processor stack loading mechanisms. LLCR metrology refers to the measurement of electrical resistance at a contact interface between two materials under low current and voltage levels. The current and voltage levels used LLCR measurements are low enough so as not to disrupt thin films (such as oxide layers) that may exist at the contact interfaces.

### BRIEF DESCRIPTION OF THE DRAWINGS

FIGS. 1A-1B are top and cross-sectional views, respectively, of an example processor stack to a socket.

FIG. 2 is a perspective view of an example LLCR testing apparatus.

FIG. 3 is an example LLCR testing method.

FIG. 4 is a block diagram of an example computing system that can perform LLCR measurements.

FIG. 5 is a block diagram of an example processor unit to execute computer-executable instructions as part of implementing technologies described herein.

### DETAILED DESCRIPTION

LLCR metrology is an important capability during socket design as it allows for the resistance at points where a processor contacts a socket to be measured Minimizing processor-to-socket contact resistance is desirable as it can cause voltage drops and heat generation as current passes through individual processor-socket connections. In high-power processors where individual processor pins or pads can draw a large amount of current, an undesirably high level of contact resistance can cause large enough voltage drops and/or heat generation to cause the processor to not perform as expected.

Existing LLCR measurement devices can have various limitations. First, they can be large and bulky, which can make them inconvenient to use due to their lack of portability. This can create long turn-around LLCR measurement times for organizations that have multiple socket designs under development at any given time as socket designs to be tested must be brought to where the LLCR measurement devices are located instead of vice versa. Second, issues with wire connections to a socket being measured can cause erroneous measurements. In some existing LLCR measure devices, wire connection issues can erroneously indicate that several percent of socket-processor contacts are electrical opens, which can be on the order of hundreds of connections in high-end server processors that have thousands of pins. Third, existing LLCR devices may not be able to physically accommodate sockets populated with large thermal management solutions. In order to test sockets populated with processors attached to large thermal management solutions, the thermal management solution may need to be physically altered. In some situations, this can involve cutting off one or more parts of the thermal management solution.

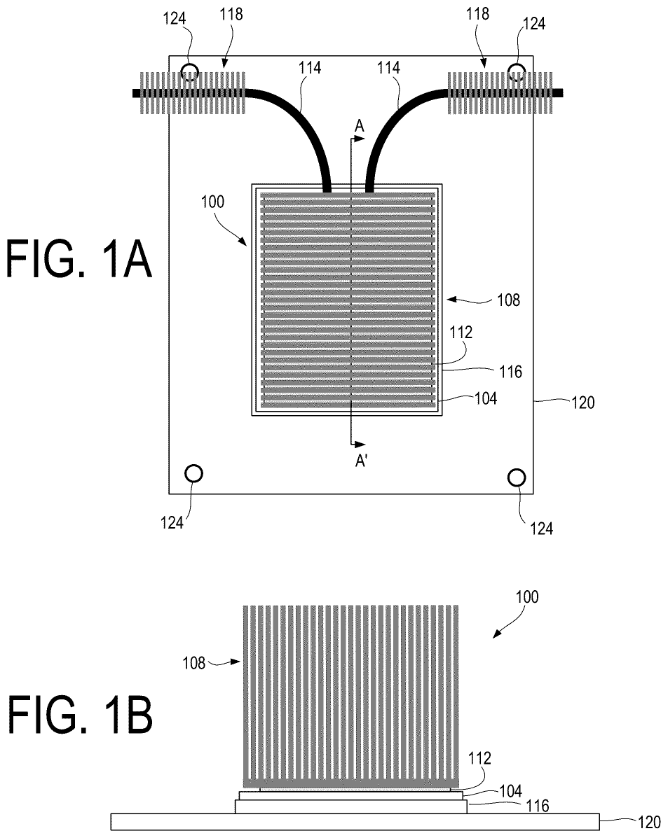

FIGS. 1A-1B are top and cross-sectional views, respectively, of an example processor stack attached to a socket. FIG. 1B is a cross-sectional view of processor stack 100 of FIG. 1A taken along the line A-A′. The processor stack 100 comprises an integrated circuit component 104 and a primary heat sink 108 attached to the integrated circuit component 104 via a layer of thermal interface material (TIM) 112. Heat pipes 114 attached at one end to the primary heat sink 108 and at a second end to a secondary heat sink 118 provide for the transport of heat from the primary heat sink 108 to the secondary heat sinks 118. The primary heat sink 108 and the secondary heat sinks 118 comprise a plurality of fins. The processor stack 100 is attached to a socket 116 that is in turn attached to a printed circuit board 120. The printed circuit board can be part of an apparatus used for LLCR measurements.

The thermal management solution illustrated in FIGS. 1A-1B can be considered to have an “outrigger” configuration due to the shape of the heat pipes 114 and the location, size, and orientation of the secondary heat sinks 118 relative to the primary heat sink 108. Thermal management solutions of the type shown in FIGS. 1A-1B may be utilized where there is more physical volume available in a computing system for additional heat exchangers (e.g., heat sinks) in addition to a heat exchanger attached to an integrated circuit component. In some embodiments, a thermal management solution comprising a primary heat sink, heat pipes, and secondary heat sinks and having the “outrigger” configuration illustrated in FIGS. 1A-1B can be an Intel® Extended Volume Air Cooling (EVAC) thermal management solution.

The printed circuit board 120 comprises alignment holes 124 that accommodate alignment pins of an LLCR testing device. The alignment pins are used to position the printed circuit board 120 during LLCR testing. As can be seen, two of the alignment holes 124 overlap with the secondary heat sinks 118. Thus, an attempt to place the printed circuit board 120 in an LLCR testing device having alignment pins that correspond with the alignment holes 124 would be unsuccessful as the secondary heat sinks 118 would interfere with the alignment pins fully extending through the alignment holes 124. Resolutions to this problem can comprise cutting the heat pipes 114 at a point between the primary heat sink 108 and the secondary heat sinks 118 or cutting off ends of the secondary heat sinks 118 to allow LLCR tester alignment pins to fully extend through the alignment holes 124. Such alteration of the thermal management solution to accommodate LLCR tester limitations may be undesirable as a processor stack with an unadulterated thermal management solution may be desired for additional testing of the processor stack, as well as preventing reuse of the thermal management solution.

Described herein are technologies pertaining to LLCR testing of socketed processors. The disclosed LLCR testing apparatus comprises a test board comprising an attached socket to which a processor can be attached and for which processor-socket contact resistances are desired to be determined. The LLCR testing apparatus further comprises a patch board that connects to a contact resistance tester and an interface board that connects to both the test board and the patch board. The LLCR testing apparatus is modular in that the test, interface, and patch boards are releasably connectable. This allows for simple and quick reconfiguration of the testing apparatus to test different socket-processor configurations. The patch board can comprise a flexible printed circuit board and thus allow for flexibility in how the interface board and test board are oriented relative to the contact resistance tester during LLCR testing. For example, if a test surface of a contact resistance tester lies in the x-y plane, the interface board and the test board can lie in the y-z plane or be oriented in any non-parallel manner relative to the test surface. The testing apparatus can be smaller than existing LLCR testers and can be used with small form factor contact resistance testers (which, in some cases, can be roughly the size of a laptop computer). For example, while some existing LLCR testers are about five feet tall and have lengths and widths of about two feet, the LLCR testing apparatus disclosed herein, in some embodiments, can be about two feet in length, about 1.3 feet in width, and about 0.3 feet in height. Thus, overall LLCR testing systems comprising the testing apparatus disclosed herein is readily portable. The LLCR testing apparatuses disclosed herein can also allow for the testing of processors with large attached thermal management solutions. Thus, the LLCR testing technologies described herein can have at least the advantages of being modular, portable, and allowing for large thermal management solutions. Further, as the test, interface, and patch interface board are directly connected, the LLCR testing apparatus may have the additional advantage of being less susceptible to wire connection issues that can result in the reporting of false open circuits.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. An integrated circuit die may include one or more transistors, supporting circuitry to route electrical signals to the transistors, passive components (e.g., signal traces, resistors, capacitors, or inductors), and/or any other integrated circuit components. In one example of an integrated circuit component, a packaged integrated circuit component contains one or more processor units mounted on a substrate with an exterior surface of the substrate comprising a pin grid array (PGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

As used herein, the term “coupling component” refers to a structure that conductively and/or mechanically couples two components, such as two printed circuit boards, a socket and a printed circuit board, or an integrated circuit component and a socket. The term coupling component can refer to pads (also referred to as contact pads or bond pads), pins (such as pogo pins), holes (that can, for example, receive pins), or other suitable structures, such as solder balls.

As used herein, the phrase “conductively coupled” refers to layers or components that are coupled to facilitate the flow of electrical current between them. For example, coupling components located on a first surface of a printed circuit board can be conductively coupled to coupling components located on a second surface of the printed circuit board by conductive traces and vias that act as interconnections between conductive traces on different metal layer of the printed circuit board.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

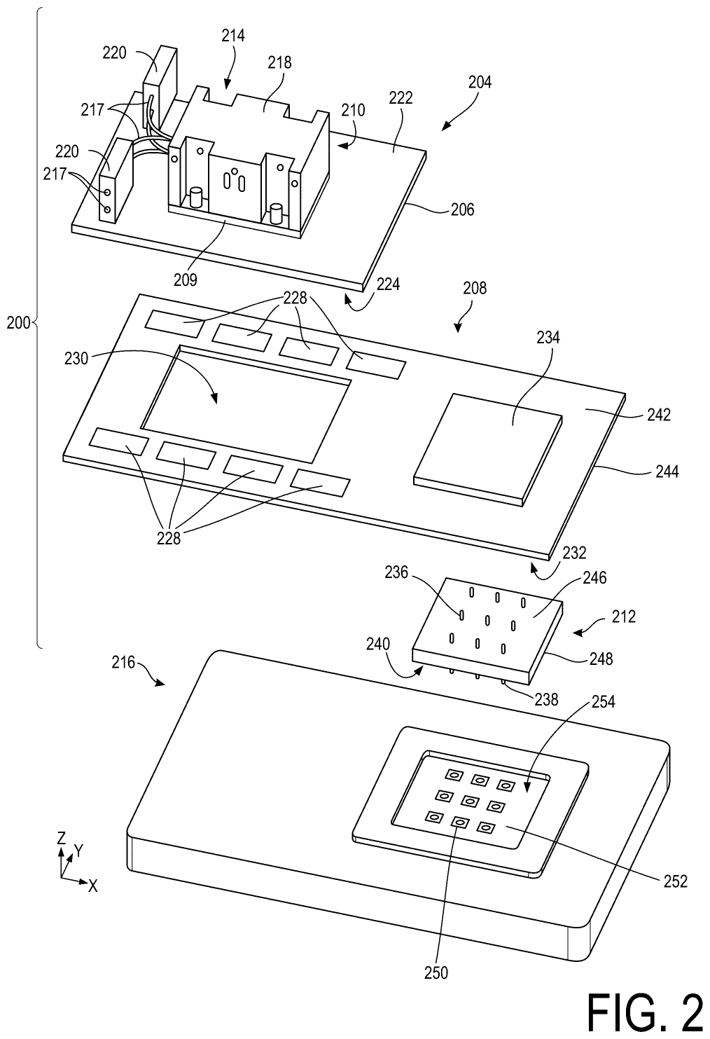

FIG. 2 is a perspective view of an example LLCR testing apparatus. The testing apparatus 200 comprises a test board 204, an interface board 208, and a patch board 212. The testing apparatus 200 connects to a contact resistance tester 216. When connected, the testing apparatus 200 and the contact resistance tester 216 can measure the resistance of contacts between an integrated circuit component attached to a socket on the test board 204. The LLCR testing apparatus 200 is modular in that the test board 204, the interface board 208, the patch board 212, and the contact resistance tester 216 are all releasably connectable.

The test board 204 comprises a printed circuit board 206 and a socket 209. The test board 204 is populated in that a processor stack 210 is attached to the socket 209. The processor stack 210 comprises an integrated circuit component (not shown) attached to a thermal management solution 214 by a layer of thermal interface material (not shown). The integrated circuit component is connected to the socket 209. The socket 209 can be any type of socket to which an integrated circuit component can attach, such as a PGA (pin grid array), LGA (land grid array), or BGA (ball grid array) socket. Thus, the integrated circuit component-socket contacts to be tested by the contact resistance tester 216 can comprise contacts between coupling components (e.g., pins, socket balls) on a surface of the integrated circuit component and coupling components on a surface of the socket (e.g., pads, holes). For example, integrated circuit component-socket contacts to be tested by the contact resistance tester 216 can comprise contacts between integrated circuit component pins and socket holes (in the case of, for example, PGA sockets), integrated circuit component pads and socket pins (in the case of, for example, LGA sockets), or integrated circuit component solder balls and socket pads (in the case of, for example, BGA sockets). The test board 204 further comprises a stiffener plate (not shown) positioned on the bottom surface 224 of the test board 204 to add structural support to the test board 204 in the vicinity of the socket 209. In other test board embodiments, a stiffener plate is not used.

The printed circuit board 206, as well as any other printed circuit board described or referenced herein, comprises multiple metal (or interconnect) layers separated from one another by layers of dielectric material (e.g., FR-4 or other fiberglass-reinforced epoxy laminate) and interconnected by electrically conductive vias. The individual metal layers comprise conductive traces. Any one or more of the metal layers may be formed in a desired circuit pattern to route electrical signals between components attached or connected to the printed circuit board.

The thermal management solution 214 is similar to the outrigger thermal management solution illustrated in FIGS. 1A-1B and comprises a primary heat sink 218 attached to the integrated circuit component via a layer of thermal interface material, secondary heat sinks 220, and heat pipes 217. The individual heat pipes 217 are attached to the primary heat sink 218 and one of the secondary heat sinks 220 and transport heat from the primary heat sink 218 to one of the secondary heat sink 220. In other embodiments, the thermal management solution attached to an integrated circuit component to be tested can comprise any suitable variation of the thermal management solution illustrated in FIG. 2 or any other suitable type of thermal management solution. Variations of the thermal management solution illustrated in FIG. 2 include the use of thermosiphons in place of heat pipes 217 and heat sinks with fins in place of the solid primary and second heat sinks 218 and 220 illustrated in FIG. 2. In other embodiments, the thermal management solution can comprise a cold plate or a vapor chamber, a thermal management solution in which the cold plate or vapor chamber is part of a closed-loop liquid cooling system (that can further comprise a heat exchanger, a pump, and one or more tubes connecting the heat exchanger to the cold plate or vapor chamber), or an immersion bath-based liquid cooling thermal management solution in which a thermal management solution attached to a processing unit is at least partially submerged in dielectric liquid during contact resistance testing. Thermal management solutions of varying sizes can be accommodated as well, such as solutions that have heights of multiple rackmount units (e.g., 1U, 2U) or thermal management solutions that have longer lengths, such as the thermal management solution illustrated in FIGS. 1A-1B. Thermal management solutions having varying sizes may be accommodated by a single test board design or different test board designs that are individually tailored to the size of a specific thermal management solution.

The printed circuit board 206 comprises a first plurality of coupling components (not shown) located on a top surface 222 of printed circuit board 206 and a second plurality of coupling components (not shown) on the bottom surface 224 of the printed circuit board 206. The first plurality of coupling components connect to the socket 209. Conductive traces and vias in the printed circuit board 206 conductively couple the first set of coupling components on the top surface 222 to the second set of coupling components on the bottom surface 224 of printed circuit board 206.

The interface board 208 comprises a printed circuit board 244 comprising a first plurality of coupling components 228, a second plurality of coupling components, and a cutout 230. The interface board 208 translates the footprint of the coupling components 236 on a top surface 246 of the patch board 212 to the footprint of the coupling components on the bottom surface 224 of the test board 204. The first plurality of coupling components 228 is located on a top surface 242 of the printed circuit board 244 and enables the interface board 208 to connect with the test board 204, and the second plurality of coupling components is located on a bottom surface 232 of the printed circuit board 244 and enables the interface board 208 to connect with the patch board 212. The first plurality of coupling components 228 are grouped into eight connector blocks, with each connector block comprising a plurality of coupling components. The eight connector blocks connect to corresponding connector blocks (each comprising a plurality of coupling components) on the bottom surface 224 of the test board 204. In other interface board embodiments, the first plurality of coupling components 228 on the printed circuit board 244 can take configurations that do not comprise coupling components grouped into connector blocks. The cutout 230 is to accommodate the stiffener plate located on the bottom surface 224 of the test board 204. In LLCR testing apparatus embodiments where the test board does not have a stiffener plate, the interface board may not comprise a cutout. The second plurality of coupling components is located on a region of the bottom surface 232 of the interface board 208 that is opposite a stiffener plate 234. In some LLCR testing apparatus embodiments, the interface board does not comprise a stiffener plate in a region of the interface board where a plurality of coupling components that connect to a contact resistance tester is located. The first plurality of coupling components 228 are conductively coupled to the second plurality of coupling components by conductive traces and vias in the printed circuit board 244. In some embodiments, the printed circuit board 244 is about 62 mils thick and has ten metal layers. The printed circuit board 244 can have a different thickness and/or comprise a different number of metal layers in other embodiments.

The contact resistance tester 216 can be any tester capable of performing LLCR measurements, such as a four-wire Kelvin measurement tool. In some embodiments, the contact resistance tester 216 can be a commercially available contact resistance tester. The contact resistance tester 216 comprises a plurality of coupling components 250 to which the second plurality of coupling components 238 of the patch board 212 connect during contact resistance testing. The plurality of coupling components 250 is located on a test surface 252 that is located within a recess 254 of the contact resistance tester 216. The contact resistance tester 216 can be portable in that it is small and light enough to be carried around by a person and can readily connect to a nearby computing system, such as a laptop computer, in a wired or wireless manner.

The LLCR testing apparatuses disclosed herein allow for contact resistance measurement of sockets having an area, length, and/or width that can exceed that of the test surface of a contact resistance tester. Put another way, an LLCR testing apparatus translates the footprint of the coupling components on a contact resistance tester test surface to the footprint of the coupling components located on the test board that connects to the socket. For example, sockets that have lengths and widths larger than the lengths of widths of test surfaces of some existing commercial contact resistance testers (which can be about 110 millimeters for some contact resistance testers) can be accommodated by the LLCR testing apparatuses disclosed herein. New test boards (and possibly new interface boards as well) can be designed for use with existing contact resistance testers as socket sizes continue to grow.

The patch board 212 comprises a printed circuit board 248 comprising the first plurality of coupling components 236 and the second plurality of coupling components 238. The first plurality of coupling components 236 are located on a top surface 246 of the printed circuit board 248 and enables the patch board 212 to connect with the interface board 208, and the second plurality of coupling components 238 is located on a bottom surface 240 of the printed circuit board 248 and enables the patch board 212 to connect with the plurality of coupling components 250 on the test surface 252 of the contact resistance tester 216. The first and second pluralities of coupling components 236 and 238 are illustrated as pins but could be other coupling components in other embodiments. The first plurality of coupling components 236 is conductively coupled to the second plurality of coupling components 238 by conductive traces and vias in the printed circuit board 248. In some embodiments, the printed circuit board 248 is about 20 mils thick and comprises four or more metal layers The printed circuit board 248 can have a different thickness and/or comprise a different number of metal layers in other embodiments.

The patch board 212 acts as a bridge that allows the interface board 208 to conductively couple to the contact resistance tester 216. That is, the width and length of the patch board 212 is smaller than the width and length of the recess so that the patch board 212 fits within the recess. The patch board further has a height that is greater than the depth of the recess. This allows the patch board to effectively provide for a translation of the coupling components 250 of the contact resistance tester 216 in the z-direction to a point above a top surface of the contact resistance tester 216.

In some embodiments, such as the one illustrated in FIG. 2, the patch board 212 is rigid. In other embodiments, the patch board comprises a flexible printed circuit board and is at least partially flexible. A patch board comprising a flexible printed circuit board can enable freedom of movement for an interface board and a test board relative to a contact resistance tester. This may allow for the interface and test boards to be conveniently positioned during testing relative to LLCR testing apparatus embodiments where the interface and test boards are in a fixed position relative to the contact resistance tester due to the LLCR testing apparatus comprising a rigid patch board.

In other embodiments, the patch board comprises a flexible printed circuit board that extends for a distance (such as six inches, one foot, two feet, or another suitable distance), which can allow for even greater LLCR testing apparatus positioning flexibility. For example, in such embodiments, the contact resistance tester can be kept in a stationary position while the interface and testing boards are manipulated during testing (such as, for example, when swapping out test boards with different socket-processor configurations). Patch boards with flexible printed circuit boards that extend for a distance can also enable the testing of processor stacks with thermal management solutions that cannot be tested using existing LLCR testers. For example, contact resistance measurements of socket-processor stack configurations having an immersion bath-based liquid cooling thermal management solution could be performed by having the thermal management solution at least partially immersed in dielectric liquid with a flexible printed circuit board running from the interface board to a contact resistance tester located away from the container containing the dielectric fluid.

The portability LLCR testing apparatus embodiments disclosed herein can allow for flexible LLCR testing in organizations that may have multiple socket designs being developed simultaneously by allowing for multiple LLCR testing systems to be deployed as needed across the organization's test labs at customer sites for testing and debugging, rather than requiring socket prototypes or sockets that have failed in the field to be brought to where existing LLCR testers are located. Portability can be important for LLCR testing of LGA sockets as LGA LLCR measurements can be sensitive to handling shock. The handling of a loaded LGA socket (which can involve transporting a loaded LGA socket from a socket development lab to an LLCR testing lab) can result in enough wear to oxide layers at socket-integrated circuit component contacts to result in LLCR measurements that vary by over an order of magnitude relative to LGA LLCR measurements of loaded LGA sockets that have not undergone handling shock. Thus, the portable LLCR testing technologies disclosed herein can reduce handling-induced LLCR measurement error by being able to bring LLCR testing solutions to the test lab instead of bringing prototype socket-integrated circuit component configurations to an LLCR tester.

In addition to being portable, the LLCR testing apparatus embodiments disclosed herein may allow for the measurement of processor stack-socket configurations having thermal management solutions that are larger than those that can be accommodated by existing LLCR testers. That is, thermal management solutions that need to be physically altered (e.g., by cutting off heat pipes or the ends of secondary heat sinks, as described above) to be tested by some existing LLCR testers may not need to be altered to be tested by an LLCR testing system comprising any of the LLCR testing apparatus disclosed herein.

The modularity of the LLCR testing apparatuses disclosed herein can allow for ease in exchanging the socket-processor stack configuration under test. To exchange the socket-processor stack configuration under test, a first test board comprising a first socket-processor stack is disconnected from the interface board of the testing apparatus 200 and a second board comprising a second socket-processor stack is connected to the interface board. The modularity of the LLCR testing apparatus technologies described herein allows for new test boards that accommodate new socket designs, processor stack configurations, and/or thermal management solutions to be used with existing interface boards and patch boards. Organizations are not thus limited to a single test board design that may limit their capability to handle a variety of thermal management solutions.

FIG. 2 illustrates one type of LLCR testing apparatus configuration—in which the test board connects to the interface board at a location on the interface board that is physically offset from where the interface board connects to the patch board. This physical offset is at least driven by the existence of the cutout 230 that accommodates the stiffening plate on the back side of the test board 204. In testing apparatus embodiments where the test board does not comprise a stiffening plate, a cutout in the interface board may not be needed and the test board can connect to the interface board at a location of the interface board that is closer to where the interface board connects to the patch board. This may result in a compact interface board design. Routing constraints may limit how much these regions may overlap as the interface board may need to route a large number of signals from a test board to a patch board.

The constituent boards (test board, interface board, patch board) of an LLCR testing apparatus can be connected by any coupling component that allows the boards to be detachably connected. For example, a pair of boards can be connected by pins on a first board contacting pads or inserting into holes on a second board. For example, pins 236 and 238 can be pogo pins that connect the patch board 212 to the interface board 208 and the contact resistance tester 216, respectively. In some embodiments, pogo pins are surface mounted to conductive contacts at a surface of a printed circuit board. In some LLCR testing apparatus embodiments, pogo pins are used for all board-to-board and board-to-tester connections (e.g., test board-interface board, interface board-patch board, patch board-tester connections). These pogo pin connections can be made by aligning the pogo pins on one board to the corresponding pads on another board and preloading the pins to for stable resistance measurements. Removing the load allows the boards to be disconnected.

The LLCR testing apparatus disclosed herein may not suffer from the wire connection issues mentioned earlier that existing LLCR testers can suffer from. As the constituent boards of the LLCR testing apparatuses disclosed herein are directly connected and the LLCR testing apparatus is directly connected to a test surface of a contact resistance tester, there are no wires that can cause wire connection issues (such as those due to, for example, poor connections and/or parasitic wire resistances). Thus, the LLCR testing apparatus technologies disclosed herein may provide more accurate LLCR measurements by reporting fewer false open circuits.

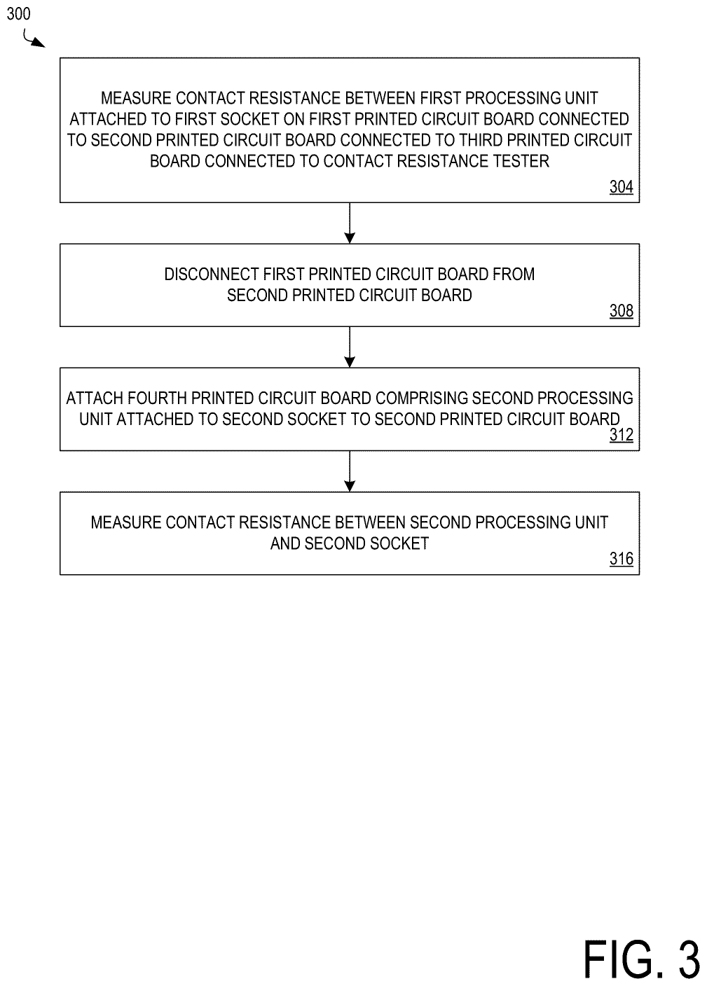

FIG. 3 is an example LLCR testing method. The method 300 can be performed by, for example, an integrated circuit component manufacturer. At 304, a first resistance of a contact between a first processing unit attached to a first socket is measured by a contact resistance tester, the first socket located on a first printed circuit board connected to a second printed circuit board, the second printed circuit board connected to a third printed circuit board, the third printed circuit board connected to a test surface of the contact resistance tester. At 308, the first printed circuit board is disconnected from the second printed circuit board after measuring the first resistance. At 312, a fourth printed circuit board is attached to the second printed circuit board, the fourth printed circuit board comprising a second processing unit attached to a second socket. At 316, a contact resistance of a contact between the second processing unit and the second socket is measured by the contact resistance tester. In other embodiments, the method 300 can comprise one or more additional actions.

The LLCR testing technologies described herein can be used to measure the contact resistance in socket-processor stack configurations implemented in any of a variety of computing systems, including mobile computing systems (e.g., smartphones, tablet computers, laptop computers), non-mobile computing systems (e.g., desktop computers, servers, workstations, rack-level computing solutions (e.g., blade, tray, or sled computing systems)), and embedded computing systems (e.g., computing systems that are part of a vehicle, smart home appliance, consumer electronics product or equipment, manufacturing equipment). As used herein, the term “computing system” includes computing devices and includes systems comprising multiple discrete physical components.

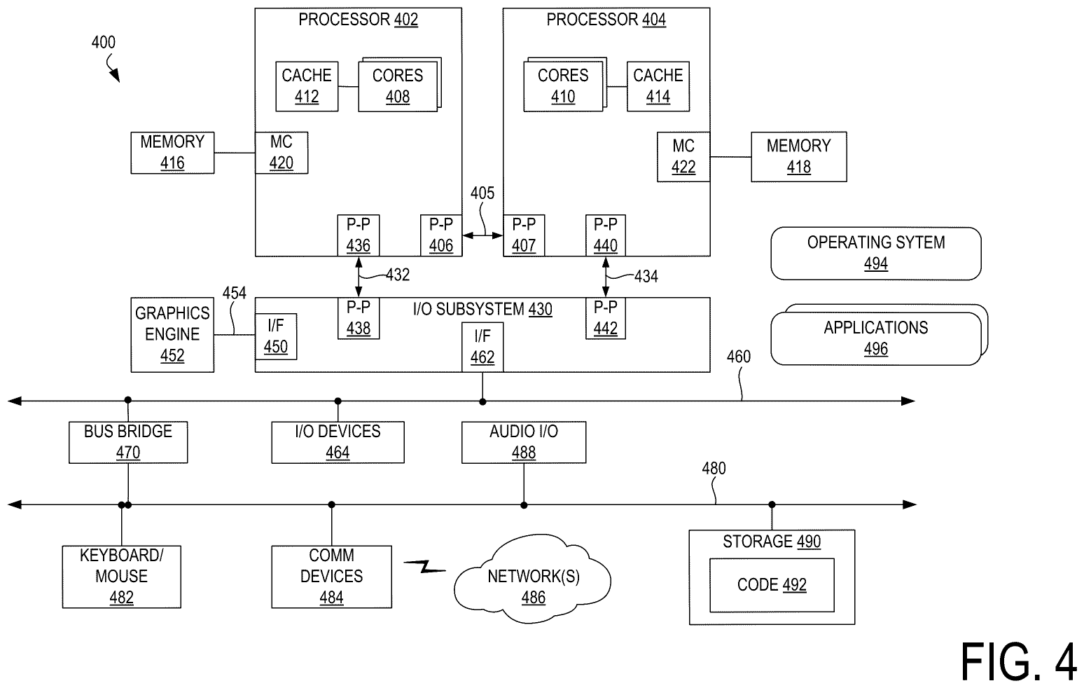

FIG. 4 is a block diagram of an example computing system that can perform LLCR measurements. Generally, components shown in FIG. 4 can communicate with other shown components, although not all connections are shown, for ease of illustration. The computing system 400 is a multiprocessor system comprising a first processor unit 402 and a second processor unit 404 comprising point-to-point (P-P) interconnects. A point-to-point (P-P) interface 406 of the processor unit 402 is coupled to a point-to-point interface 407 of the processor unit 404 via a point-to-point interconnection 405. It is to be understood that any or all of the point-to-point interconnects illustrated in FIG. 4 can be alternatively implemented as a multi-drop bus, and that any or all buses illustrated in FIG. 4 could be replaced by point-to-point interconnects.

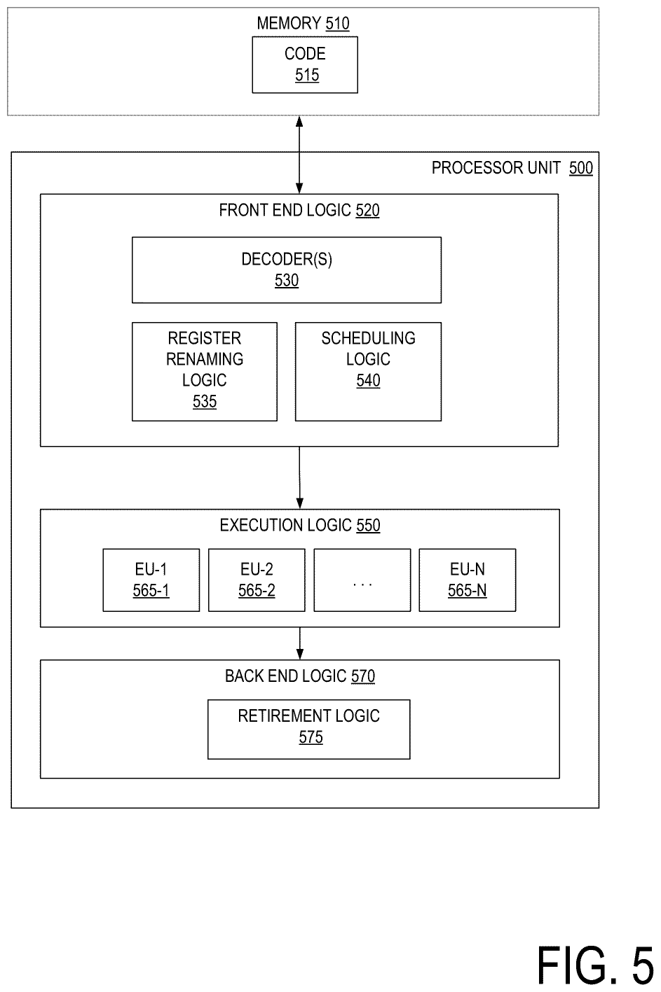

The processor units 402 and 404 comprise multiple processor cores. Processor unit 402 comprises processor cores 408 and processor unit 404 comprises processor cores 410. Processor cores 408 and 410 can execute computer-executable instructions in a manner similar to that discussed below in connection with FIG. 5, or other manners.

Processor units 402 and 404 further comprise cache memories 412 and 414, respectively. The cache memories 412 and 414 can store data (e.g., instructions) utilized by one or more components of the processor units 402 and 404, such as the processor cores 408 and 410. The cache memories 412 and 414 can be part of a memory hierarchy for the computing system 400. For example, the cache memories 412 can locally store data that is also stored in a memory 416 to allow for faster access to the data by the processor unit 402. In some embodiments, the cache memories 412 and 414 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 400 is shown with two processor units, the computing system 400 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

Processor units 402 and 404 further comprise memory controller logic (MC) 420 and 422. As shown in FIG. 4, MCs 420 and 422 control memories 416 and 418 coupled to the processor units 402 and 404, respectively. The memories 416 and 418 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 420 and 422 are illustrated as being integrated into the processor units 402 and 404, in alternative embodiments, the MCs can be external to a processor unit.

Processor units 402 and 404 are coupled to an Input/Output (I/O) subsystem 430 via point-to-point interconnections 432 and 434. The point-to-point interconnection 432 connects a point-to-point interface 436 of the processor unit 402 with a point-to-point interface 438 of the I/O subsystem 430, and the point-to-point interconnection 434 connects a point-to-point interface 440 of the processor unit 404 with a point-to-point interface 442 of the I/O subsystem 430. Input/Output subsystem 430 further includes an interface 450 to couple the I/O subsystem 430 to a graphics engine 452. The I/O subsystem 430 and the graphics engine 452 are coupled via a bus 454.

The Input/Output subsystem 430 is further coupled to a first bus 460 via an interface 462. The first bus 460 can be a Peripheral Component Interconnect Express (PCIe) bus or any other type of bus. Various I/O devices 464 can be coupled to the first bus 460. A bus bridge 470 can couple the first bus 460 to a second bus 480. In some embodiments, the second bus 480 can be a low pin count (LPC) bus. Various devices can be coupled to the second bus 480 including, for example, a keyboard/mouse 482, audio I/O devices 488, and a storage device 490, such as a hard disk drive, solid-state drive, or another storage device for storing computer-executable instructions (code) 492 or data. The code 492 can comprise computer-executable instructions for performing methods described herein. Additional components that can be coupled to the second bus 480 include communication device(s) 484, which can provide for communication between the computing system 400 and one or more wired or wireless networks 486 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 402.11 standard and its supplements).

In embodiments where the communication devices 484 support wireless communication, the communication devices 484 can comprise wireless communication components coupled to one or more antennas to support communication between the computing system 400 and external devices. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The system 400 can comprise removable memory such as flash memory cards (e.g., SD (Secure Digital) cards), memory sticks, Subscriber Identity Module (SIM) cards). The memory in system 400 (including caches 412 and 414, memories 416 and 418, and storage device 490) can store data and/or computer-executable instructions for executing an operating system 494 and application programs 496. Example data includes web pages, text messages, images, sound files, video data, and LLCR measurement data to be sent to and/or received from one or more network servers or other devices by the system 400 via the one or more wired or wireless networks 486, or for use by the system 400. The system 400 can also have access to external memory or storage (not shown) such as external hard drives or cloud-based storage.

The operating system 494 can control the allocation and usage of the components illustrated in FIG. 4 and support the one or more application programs 496. The application programs 496 can include common computing system applications (e.g., email applications, calendars, contact managers, web browsers, messaging applications) as well as other computing applications, such as an LLCR measurement application.

The computing system 400 can support various additional input devices, such as a touchscreen, microphone, camera, trackball, touchpad, light sensor, and one or more output devices, such as one or more displays. Other possible input and output devices include piezoelectric and other haptic I/O devices. Any of the input or output devices can be internal to, external to, or removably attachable with the system 400. External input and output devices can communicate with the system 400 via wired or wireless connections. The computing system 400 can further support an LLCR test surface, such as test surface 252 (FIG. 2). The computing system can cause electrical signals to be driven at coupling components located on the test surface and to measure electrical signals at coupling components located on the test surface.

The system 400 can further include at least one input/output port comprising physical connectors (e.g., USB, IEEE 1394 (FireWire), Ethernet, RS-232), and a power supply (e.g., battery). The computing system 400 can further comprise one or more antennas coupled to one or more receivers, transmitters, and/or transceivers to enable wireless communication-related functions.

It is to be understood that FIG. 4 illustrates only one example computing system architecture. Computing systems based on alternative architectures can be used to implement technologies described herein. For example, instead of the processors 402 and 404 and the graphics engine 452 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 4. Moreover, the illustrated components in FIG. 4 are not required or all-inclusive, as shown components can be removed and other components added in alternative embodiments.

FIG. 5 is a block diagram of an example processor unit 500 to execute computer-executable instructions as part of implementing technologies described herein. The processor unit 500 can be a single-threaded core or a multithreaded core in that it may include more than one hardware thread context (or “logical processor”) per processor unit.

FIG. 5 also illustrates a memory 510 coupled to the processor unit 500. The memory 510 can be any memory described herein or any other memory known to those of skill in the art. The memory 510 can store computer-executable instructions 515 (code) executable by the processor unit 500.

The processor unit comprises front-end logic 520 that receives instructions from the memory 510. An instruction can be processed by one or more decoders 530. The decoder 530 can generate as its output a micro-operation such as a fixed width micro operation in a predefined format, or generate other instructions, microinstructions, or control signals, which reflect the original code instruction. The front-end logic 520 further comprises register renaming logic 535 and scheduling logic 540, which generally allocate resources and queues operations corresponding to converting an instruction for execution.

The processor unit 500 further comprises execution logic 550, which comprises one or more execution units (EUs) 565-1 through 565-N. Some processor unit embodiments can include a number of execution units dedicated to specific functions or sets of functions. Other embodiments can include only one execution unit or one execution unit that can perform a particular function. The execution logic 550 performs the operations specified by code instructions. After completion of execution of the operations specified by the code instructions, back-end logic 570 retires instructions using retirement logic 575. In some embodiments, the processor unit 500 allows out of order execution but requires in-order retirement of instructions. Retirement logic 575 can take a variety of forms as known to those of skill in the art (e.g., re-order buffers or the like).

The processor unit 500 is transformed during execution of instructions, at least in terms of the output generated by the decoder 530, hardware registers and tables utilized by the register renaming logic 535, and any registers (not shown) modified by the execution logic 550.

Any of the disclosed methods (or a portion thereof) can be implemented as computer-executable instructions or a computer program product. Such instructions can cause a computing system or one or more processor units capable of executing computer-executable instructions to perform any of the disclosed methods. As used herein, the term “computer” refers to any computing system, device, or machine described or mentioned herein as well as any other computing system, device, or machine capable of executing instructions. Thus, the term “computer-executable instruction” refers to instructions that can be executed by any computing system, device, or machine described or mentioned herein as well as any other computing system, device, or machine capable of executing instructions.

The computer-executable instructions or computer program products as well as any data created and/or used during implementation of the disclosed technologies can be stored on one or more tangible or non-transitory computer-readable storage media, such as volatile memory (e.g., DRAM, SRAM), non-volatile memory (e.g., flash memory, chalcogenide-based phase-change non-volatile memory) optical media discs (e.g., DVDs, CDs), and magnetic storage (e.g., magnetic tape storage, hard disk drives). Computer-readable storage media can be contained in computer-readable storage devices such as solid-state drives, USB flash drives, and memory modules. Alternatively, any of the methods disclosed herein (or a portion) thereof may be performed by hardware components comprising non-programmable circuitry. In some embodiments, any of the methods herein can be performed by a combination of non-programmable hardware components and one or more processing units executing computer-executable instructions stored on computer-readable storage media.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a first printed circuit board comprising a socket attached to a first surface of the first printed circuit board, a first plurality of coupling components located on the first surface of the first printed circuit board, a second plurality of coupling components located on a second surface of the first printed circuit board, the socket attached to the first printed circuit board via the first plurality of coupling components, the first plurality of coupling components conductively coupled to the second plurality of coupling components by the first printed circuit board; a second printed circuit board comprising a third plurality of coupling components located on a first surface of the second printed circuit board and a fourth plurality of coupling components located on a second surface of the second printed circuit board, the third plurality of coupling components conductively coupled to the fourth plurality of coupling components by the second printed circuit board; and a third printed circuit board comprising a fifth plurality of coupling components located on a first surface of the third printed circuit board and a sixth plurality of coupling components located on a second surface of the third printed circuit board, the fifth plurality of coupling components conductively coupled to the sixth plurality of coupling components by the third printed circuit board, the third printed circuit board connectable to a contact resistance tester by the sixth plurality of coupling components.

Example 2 comprises the apparatus of Example 1, wherein the second printed circuit board is connectable to the first printed circuit board through connection of the second plurality of coupling components to the third plurality of coupling components.

Example 3 comprises the apparatus of Example 1, wherein the second printed circuit board is connectable to the third printed circuit board through connection of the fourth plurality of coupling components to the fifth plurality of coupling components.

Example 4 comprises the apparatus of any one of Examples 1-3, wherein the sixth plurality of coupling components comprises a plurality of pogo pins.

Example 5 comprises the apparatus of any one of Examples 1-4, further comprising a processing unit attached to the socket.

Example 6 comprises the apparatus of Example 5, further comprising a heat sink attached to the processing unit.

Example 7 comprises the apparatus of Example 6, wherein the heat sink is a first heat sink, the apparatus further comprising: a second heat sink; a first heat transfer device attached at a first end of the first heat transfer device to the second heat sink and attached at a second end of the first heat transfer device to the first heat sink; a third heat sink; and a second heat transfer device attached at a first end of the second heat transfer device to the third heat sink and attached at a second end of the second heat transfer device to the third heat sink.

Example 8 comprises the apparatus of Example 7, wherein the first heat transfer device comprises a heat pipe or a thermosiphon.

Example 9 comprises the apparatus of Example 5, further comprising: a vapor chamber attached to the processing unit; a heat sink attached to the vapor chamber; and a heat exchanger attached to the vapor chamber by one or more tubes.

Example 10 comprises the apparatus of any one of Examples 1-9, further comprising the contact resistance tester.

Example 11 comprises the apparatus of any one of Examples 1-10, wherein apparatus is portable.

Example 12 comprises the apparatus of any one of Example 1-11, wherein the third printed circuit board comprises a flexible printed circuit board.

Example 13 comprises the apparatus of Example 12, wherein the flexible printed circuit board enables the first printed circuit board and the second printed circuit board to be oriented in a non-parallel manner relative to a test surface of the contact resistance tester.

Example 14 comprises the apparatus of Example 10, wherein the contact resistance tester comprises a test surface that has a first area, the second plurality of coupling components defining a second area, the second area greater than the first area.

Example 15 comprises the apparatus of Example 10, wherein the contact resistance tester comprises a test surface having a first length and a first width, an area defined by the second plurality of coupling components having a second length and second width, and the second length is greater than the first length or the second width is greater than the first width.

Example 16 comprises the apparatus of Example 10, further comprising a contact resistance tester comprising a test surface located in a recess of the contact resistance tester, the recess having a depth, the third printed circuit board having a height that is greater than the depth of the recess.

Example 17 comprises an apparatus comprising: a contact resistance tester; a first printed circuit board comprising a socket attached to a first surface of the first printed circuit board, a first plurality of coupling components located on the first surface of the first printed circuit board, a second plurality of coupling components located on a second surface of the first printed circuit board, the socket attached to the first printed circuit board via the first plurality of coupling components, the first plurality of coupling components conductively coupled to the second plurality of coupling components by the first printed circuit board; a second printed circuit board comprising a third plurality of coupling components located on a first surface of the second printed circuit board and a fourth plurality of coupling components located on a second surface of the second printed circuit board, the third plurality of coupling components conductively coupled to the fourth plurality of coupling components by the second printed circuit board; and a third printed circuit board comprising a fifth plurality of coupling components located on a first surface of the third printed circuit board and a sixth plurality of coupling components located on a second surface of the third printed circuit board, the fifth plurality of coupling components conductively coupled to the sixth plurality of coupling components by the third printed circuit board, the third printed circuit board is connected to the contact resistance tester by the sixth plurality of coupling components.

Example 18 comprises the apparatus of Example 17, wherein the second printed circuit board is connectable to the first printed circuit board through connection of the second plurality of coupling components to the third plurality of coupling components.

Example 19 comprises the apparatus of Example 17, wherein the second printed circuit board is connectable to the third printed circuit board through connection of the fourth plurality of coupling components to the fifth plurality of coupling components.

Example 20 comprises the apparatus of any one of Examples 17-19, wherein the sixth plurality of coupling components comprises a plurality of pogo pins.

Example 21 comprises the apparatus of any one of Examples 17-20, further comprising a processing unit attached to the socket.

Example 22 comprises the apparatus of Example 21, further comprising a heat sink attached to the processing unit.

Example 23 comprises the apparatus of Example 22, wherein the heat sink is a first heat sink, the apparatus further comprising: a second heat sink; a first heat transfer device attached at a first end of the first heat transfer device to the second heat sink and attached at a second end of the first heat transfer device to the first heat sink; a third heat sink; and a second heat transfer device attached at a first end of the second heat transfer device to the third heat sink and attached at a second end of the second heat transfer device to the third heat sink.

Example 24 comprises the apparatus of Example 23, wherein the first heat transfer device comprises a heat pipe or a thermosiphon.

Example 25 comprises the apparatus of Example 21, further comprising: a vapor chamber attached to the processing unit; a heat sink attached to the vapor chamber; and a heat exchanger attached to the vapor chamber by one or more tubes.

Example 26 comprises the apparatus of any one of Examples 17-25, wherein apparatus is portable.

Example 27 comprises the apparatus of any one of Example 17-26, wherein the third printed circuit board comprises a flexible printed circuit board.

Example 28 comprises the apparatus of Example 27, wherein the flexible printed circuit board enables the first printed circuit board and the second printed circuit board to be oriented in a non-parallel manner relative to a test surface of the contact resistance tester.

Example 29 comprises the apparatus of Example 17, wherein the contact resistance tester comprises a test surface that occupies a first area, the second plurality of coupling components occupies a second area, the second area greater than the first area.

Example 30 comprises the apparatus of Example 17, wherein the contact resistance tester comprises a test surface having a first length and a first width, an area defined by the second plurality of coupling components having a second length and second width, and the second length is greater than the first length or the second width is greater than the first width.

Example 31 comprises the apparatus of Example 17, further comprising a contact resistance tester comprising a test surface located in a recess of the contact resistance tester, the recess having a depth, the third printed circuit board having a height that is greater than the depth of the recess.

Example 32 comprises a method comprising: measuring, by a contact resistance tester, a first resistance of a contact between a first processing unit attached to a first socket, the first socket located on a first printed circuit board connected to a second printed circuit board, the second printed circuit board connected to a third printed circuit board, the third printed circuit board connected to a test surface of the contact resistance tester; disconnecting the first printed circuit board from the second printed circuit board after measuring the first resistance; attaching a fourth printed circuit board to the second printed circuit board, the fourth printed circuit board comprising a second processing unit attached to a second socket; and measuring, by the contact resistance tester, a contact resistance of a contact between the second processing unit and the second socket.

Example 33 comprises the method of Example 32, wherein, the first printed circuit board connects to the second printed circuit board via a first plurality of coupling components located on a surface of the first printed circuit board connecting to a second plurality of coupling components located on a first surface of the second printed circuit board, the second printed circuit board connects to the third printed circuit board via a third plurality of coupling components located on a second surface of the second printed circuit board connecting to a fourth plurality of coupling components located on a third surface of the third printed circuit board, the third printed circuit board connecting to the test surface of the contact resistance tester via a fifth plurality of coupling components connecting to a sixth plurality located on the test surface.

Example 34 comprises the method of Example 32, wherein a heat sink is attached to the first processing unit and the heat sink is at least partially submerged in a dielectric liquid during measuring of the first resistance.

Example 35 comprises an apparatus comprising: a contact resistance tester comprising a test surface; and a connection means for conductively coupling a socket to a plurality of coupling components on the test surface, a processing unit attached to the socket, a first area defined by where the socket connects to the connection means is being larger than a second area defined by where a plurality of coupling components on the test surface connects to the connection means.

Example 36 comprises the apparatus of Example 35, further comprising a heat sink attached to the processing unit.

Example 37 comprises the apparatus of Example 36, wherein the heat sink is a first heat sink, the apparatus further comprising: a second heat sink; a first heat transfer device attached at a first end of the first heat transfer device to the second heat sink and attached at a second end of the first heat transfer device to the first heat sink; a third heat sink; and a second heat transfer device attached at a first end of the second heat transfer device to the third heat sink and attached at a second end of the second heat transfer device to the third heat sink.

Example 38 comprises the apparatus of Example 35, further comprising: a vapor chamber attached to the processing unit; a heat sink attached to the vapor chamber; and a heat exchanger attached to the vapor chamber by one or more tubes.

Example 39 comprises the apparatus of any one of Examples 35-38, wherein apparatus is portable.

1. An apparatus comprising:
a first printed circuit board comprising a socket attached to a first surface of the first printed circuit board, a first plurality of coupling components located on the first surface of the first printed circuit board, a second plurality of coupling components located on a second surface of the first printed circuit board, the socket attached to the first printed circuit board via the first plurality of coupling components, the first plurality of coupling components conductively coupled to the second plurality of coupling components by the first printed circuit board;
a second printed circuit board comprising a third plurality of coupling components located on a first surface of the second printed circuit board and a fourth plurality of coupling components located on a second surface of the second printed circuit board, the third plurality of coupling components conductively coupled to the fourth plurality of coupling components by the second printed circuit board; and
a third printed circuit board comprising a fifth plurality of coupling components located on a first surface of the third printed circuit board and a sixth plurality of coupling components located on a second surface of the third printed circuit board, the fifth plurality of coupling components conductively coupled to the sixth plurality of coupling components by the third printed circuit board, the third printed circuit board connectable to a contact resistance tester by the sixth plurality of coupling components.

2. The apparatus of claim 1, wherein the second printed circuit board is connectable to the first printed circuit board through connection of the second plurality of coupling components to the third plurality of coupling components, and the second printed circuit board is connectable to the third printed circuit board through connection of the fourth plurality of coupling components to the fifth plurality of coupling components.

3. The apparatus of claim 1, wherein the sixth plurality of coupling components comprises a plurality of pogo pins.

4. The apparatus of claim 1, further comprising a processing unit attached to the socket.

5. The apparatus of claim 4, further comprising a heat sink attached to the processing unit.

6. The apparatus of claim 1, further comprising the contact resistance tester.

7. The apparatus of claim 6, wherein the third printed circuit board comprises a flexible printed circuit board, wherein the flexible printed circuit board enables the first printed circuit board and the second printed circuit board to be oriented in a non-parallel manner relative to a test surface of the contact resistance tester.

8. The apparatus of claim 6, wherein the contact resistance tester comprises a test surface that has a first area, the second plurality of coupling components defining a second area, the second area greater than the first area.

9. The apparatus of claim 6, further comprising a contact resistance tester comprising a test surface located in a recess of the contact resistance tester, the recess having a depth, the third printed circuit board having a height that is greater than the depth of the recess.

10. An apparatus comprising:
a contact resistance tester;
a first printed circuit board comprising a socket attached to a first surface of the first printed circuit board, a first plurality of coupling components located on the first surface of the first printed circuit board, a second plurality of coupling components located on a second surface of the first printed circuit board, the socket attached to the first printed circuit board via the first plurality of coupling components, the first plurality of coupling components conductively coupled to the second plurality of coupling components by the first printed circuit board;
a second printed circuit board comprising a third plurality of coupling components located on a first surface of the second printed circuit board and a fourth plurality of coupling components located on a second surface of the second printed circuit board, the third plurality of coupling components conductively coupled to the fourth plurality of coupling components by the second printed circuit board; and
a third printed circuit board comprising a fifth plurality of coupling components located on a first surface of the third printed circuit board and a sixth plurality of coupling components located on a second surface of the third printed circuit board, the fifth plurality of coupling components conductively coupled to the sixth plurality of coupling components by the third printed circuit board, the third printed circuit board is connected to the contact resistance tester by the sixth plurality of coupling components.

11. The apparatus of claim 10, wherein the second printed circuit board is connectable to the first printed circuit board through connection of the second plurality of coupling components to the third plurality of coupling components and the second printed circuit board is connectable to the third printed circuit board through connection of the fourth plurality of coupling components to the fifth plurality of coupling components.

12. The apparatus of claim 10, further comprising a processing unit attached to the socket.

13. The apparatus of claim 12, further comprising:
a first heat sink attached to the processing unit;
a second heat sink;
a first heat transfer device attached at a first end of the first heat transfer device to the second heat sink and attached at a second end of the first heat transfer device to the first heat sink;
a third heat sink; and
a second heat transfer device attached at a first end of the second heat transfer device to the third heat sink and attached at a second end of the second heat transfer device to the third heat sink.

14. The apparatus of claim 12, further comprising:
a vapor chamber attached to the processing unit;
a heat sink attached to the vapor chamber; and
a heat exchanger attached to the vapor chamber by one or more tubes.

15. The apparatus of claim 10, wherein the third printed circuit board comprises a flexible printed circuit board, wherein the flexible printed circuit board enables the first printed circuit board and the second printed circuit board to be oriented in a non-parallel manner relative to a test surface of the contact resistance tester.

16. The apparatus of claim 10, wherein the contact resistance tester comprises a test surface having a first length and a first width, an area defined by the second plurality of coupling components having a second length and second width, and the second length is greater than the first length or the second width is greater than the first width.

17. The apparatus of claim 10, further comprising a contact resistance tester comprising a test surface located in a recess of the contact resistance tester, the recess having a depth, the third printed circuit board having a height that is greater than the depth of the recess.

18. A method comprising:
measuring, by a contact resistance tester, a first resistance of a contact between a first processing unit attached to a first socket, the first socket located on a first printed circuit board connected to a second printed circuit board, the second printed circuit board connected to a third printed circuit board, the third printed circuit board connected to a test surface of the contact resistance tester;
disconnecting the first printed circuit board from the second printed circuit board after measuring the first resistance;
attaching a fourth printed circuit board to the second printed circuit board, the fourth printed circuit board comprising a second processing unit attached to a second socket; and
measuring, by the contact resistance tester, a contact resistance of a contact between the second processing unit and the second socket.

19. The method of claim 18, wherein, the first printed circuit board connects to the second printed circuit board via a first plurality of coupling components located on a surface of the first printed circuit board connecting to a second plurality of coupling components located on a first surface of the second printed circuit board, the second printed circuit board connects to the third printed circuit board via a third plurality of coupling components located on a second surface of the second printed circuit board connecting to a fourth plurality of coupling components located on a third surface of the third printed circuit board, the third printed circuit board connecting to the test surface of the contact resistance tester via a fifth plurality of coupling components connecting to a sixth plurality located on the test surface.

20. The method of claim 18, wherein a heat sink is attached to the first processing unit and the heat sink is at least partially submerged in a dielectric liquid during measuring of the first resistance.
